(19) United States
(12) Patent Application Publication
(10) Pub. No.: US 2025/0077476 A1
(43) Pub. Date: Mar. 6, 2025

(54) Techniques for Massively Parallel Graphics Processing Unit (GPU) Based Compression

(71) Applicant: REGENTS OF THE UNIVERSITY OF MICHIGAN, Ann Arbor, MI (US)

(72) Inventors: Ryan Landvater, Ypsilanti, MI (US); Ulysses Balis, Ypsilanti, MI (US)

(21) Appl. No.: 18/817,142

(22) Filed: Aug. 27, 2024

Related U.S. Application Data
(60) Provisional application No. 63/579,271, filed on Aug. 28, 2023.

(51) Int. Cl. G06F 16/174

(52) U.S. Cl. CPC G06F 16/1744

(57) ABSTRACT

Technologies for massively parallel data compression are disclosed. An example method includes receiving a data file, establishing a global offset at a first data of the data file, and substantially simultaneously causing a plurality of threads of a graphics processing unit (GPU) to compare respective data sequences with a first data sequence that includes the first data. Each thread of the plurality of threads may compare a different respective data sequence, and each respective data sequence may be offset from every other respective data sequence and the first data sequence. The example method may further include determining a optimal data sequence corresponding to the first data sequence from the respective data sequences, storing the optimal data sequence in a reference table, updating the global offset based on the optimal data sequence, and iteratively performing these steps until the global offset is a beginning or an end of the data file.

### CROSS-REFERENCE TO RELATED APPLICATIONS

This application claims the benefit of U.S. Application No. 63/579,271, filed Aug. 28, 2023, and entitled “Techniques for Massively Parallel Graphics Processing Unit (GPU) Based Compression”, which is incorporated herein by reference in its entirety.

### FIELD OF THE DISCLOSURE

The present disclosure relates generally to digital file compression techniques and, more particularly, to techniques for massively parallel graphics processing unit (GPU) based compression.

### BACKGROUND

The background description provided herein is for the purpose of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

Digital data usage in modern society continues to increase, such that methods for efficiently storing such data are correspondingly becoming more valuable. One common implementation to achieve efficient data storage is through data compression. These compression mechanisms can take many forms, each of which have their respective drawbacks.

Namely, conventional data compression techniques pose a fundamental trade-off between compression speed and compression ratio. For many conventional data compression algorithms (e.g., universal lossless data compression algorithms), higher compression speeds result in a less intense search for optimal repeat sequences, yielding lower compression ratios. On the other hand, such universal lossless data compression techniques favoring higher compression ratios typically require significant processing resources and time to search for the longest repeat sequences to thereby achieve the higher compression ratios.

These issues are typically further compounded when decompressing the compressed data blocks. The higher compression speed techniques typically produce a less efficient encoding as a result of the smaller length of usable repeat sequences. Consequently, these conventional techniques frequently experience slower data decompression times due to the relatively larger number of copy commands per arithmetic transactions stemming from the less efficient encoding.

Therefore, there is a need for a massively parallel GPU based compression techniques that provide high compression speeds while simultaneously achieving high compression ratios.

### SUMMARY OF THE INVENTION

According to an aspect of the present disclosure, a method for massively parallel data compression is disclosed. The method comprises: (a) receiving, at one or more processors, a data file; (b) establishing, by the one or more processors, a global offset at a first data of the data file; (c) substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence; (d) determining, by the one or more processors, an optimal data sequence that minimizes non-matched data and maximizes matched data, the optimal data sequence corresponding to the first data sequence from the respective data sequences; (e) storing, by the one or more processors, the optimal data sequence in a reference table; (f) updating, by the one or more processors, the global offset based on the optimal data sequence; and (g) iteratively performing steps (c)-(f) until the global offset is a beginning or an end of the data file.

In a variation of this aspect, storing the optimal data sequence in the reference table may further comprise: storing, by the one or more processors, (i) a reference location and (ii) a length value of the optimal data sequence in the reference table.

In another variation of this aspect, the optimal data sequence may include (i) a reference sequence or (ii) a literal sequence. Further in this variation, the computer-implemented method may further comprise: responsive to determining that the optimal data sequence is a literal sequence, storing the length of the literal sequence and a reference location of the literal sequence in a literal table.

In yet another variation of this aspect, the data file may include image data.

In still another variation of this aspect, the number of threads corresponding to the plurality of threads may equal a number of bytes in the data file.

In yet another variation of this aspect, the computer-implemented method may further comprise: receiving, by the one or more processors and after step (g), a search query to identify a feature represented in the data file; and searching, by the one or more processors, the data file based on the reference table.

In still another variation of this aspect, the computer-implemented method may further comprise: storing, by the one or more processors at step (g), a reference representing a location of the first data sequence relative to (i) the beginning of the data file or (ii) the global offset.

In yet another variation of this aspect, the global offset may be a first global offset, and updating the first global offset based on the optimal data sequence may further comprise: establishing a second global offset at a first data location within the data file that is a distance from the first global offset represented by a length value of the optimal data sequence.

In still another variation of this aspect, the computer-implemented method may further comprise: calculating, by the one or more processors, an offset value and a length value for each data sequence in the reference table; and compressing, by the one or more processors, the reference table using an entropy encoding algorithm.

In yet another variation of this aspect, the computer-implemented method may further comprise: determining, by the one or more processors, that at least two data sequences with length values corresponding to the optimal data sequence are generated by two different threads of the plurality of threads; determining, by the one or more processors, that a first data sequence of the at least two data sequences has a higher index value than a second data sequence of the at least two data sequences; and storing, by the one or more processors, the first data sequence in the reference table.

In still another variation of this aspect, the computer-implemented method may further comprise: comparing, by the one or more processors, a length value of the optimal data sequence with a match length threshold value; responsive to determining that the length value does not exceed the match length threshold value, determining, by the one or more processors, a second optimal data sequence; and responsive to determining that a second length value of the second optimal data sequence exceeds the match length threshold value, storing, by the one or more processors, the second optimal data sequence in the reference table.

In yet another variation of this aspect, the computer-implemented method may further comprise: at each iteration of steps (c)-(f), calculating, by the one or more processors, a compression index score for each thread of the plurality of threads by subtracting a respective number of non-matching characters from a respective number of matching characters; and determining, by the one or more processors, a maximum compression index score from the compression index score for each thread of the plurality of threads.

In still another variation of this aspect, the computer-implemented method may further comprise: calculating, by the one or more processors, a combined compression index score for each respective pair of threads from the plurality of threads by subtracting a number of overlapping matching characters and a number of residual non-matching characters from a combined number of matching characters; and determining, by the one or more processors, a maximum combined compression index score from the combined compression index score for the each respective pair of threads of the plurality of threads.

According to an aspect of the present disclosure, a system for massively parallel data compression is disclosed. The system may comprise: a memory storing a set of computer-readable instructions; and one or more processors interfacing with the user interface and the memory, and configured to execute the set of computer-readable instructions to cause the one or more processors to: (a) receive a data file, (b) establish a global offset at a first data of the data file, (c) substantially simultaneously cause a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence, (d) determine an optimal data sequence corresponding to the first data sequence from the respective data sequences, (e) store the optimal data sequence in a reference table, (f) update the global offset based on the optimal data sequence, and (g) iteratively perform steps (c)-(f) until the global offset is a beginning or an end of the data file.

In a variation of this aspect, the instructions, when executed, may further cause the one or more processors to store the optimal data sequence in the reference table by: storing (i) a reference location and (ii) a length value of the optimal data sequence in the reference table.

In another variation of this aspect, the optimal data sequence may include (i) a reference sequence or (ii) a literal sequence, and wherein the instructions, when executed, further cause the one or more processors to: responsive to determining that the optimal data sequence is a literal sequence, store the length of the literal sequence and a reference location of the literal sequence in a literal table.

In yet another variation of this aspect, the data file may include image data, and the number of threads corresponding to the plurality of threads may equal a number of bytes in the data file.

In still another variation of this aspect, the global offset may be a first global offset, and the instructions, when executed, may further cause the one or more processors to update the first global offset based on the optimal data sequence by: establishing a second global offset at a first data location within the data file that is a distance from the first global offset represented by a length value of the optimal data sequence.

In yet another variation of this aspect, the instructions, when executed, may further cause the one or more processors to: calculate an offset value and a length value for each data sequence in the reference table; and compress the reference table using an entropy encoding algorithm.

According to an aspect of the present disclosure, a non-transitory computer-readable storage medium having stored thereon a set of instructions, executable by at least one processor, for massively parallel data compression is disclosed. The instructions may comprise: (a) instructions for receiving a data file; (b) instructions for establishing a global offset at a first data of the data file; (c) instructions for substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence; (d) instructions for determining an optimal data sequence corresponding to the first data sequence from the respective data sequences; (e) instructions for storing the optimal data sequence in a reference table; (f) instructions for updating the global offset based on the optimal data sequence; and (g) instructions for iteratively performing steps (c)-(f) until the global offset is a beginning or an end of the data file.

### BRIEF DESCRIPTION OF THE DRAWINGS

The figures described below depict various aspects of the system and methods disclosed herein. It should be understood that each figure depicts an embodiment of a particular aspect of the disclosed system and methods, and that each of the figures is intended to accord with a possible embodiment thereof. Further, wherever possible, the following description refers to the reference numerals included in the following figures, in which features depicted in multiple figures are designated with consistent reference numerals.

FIG. 1 illustrates an example computing environment for massively parallel data compression, in accordance various aspects disclosed herein.

FIG. 2 illustrates an exemplary relative index mapping performed by components of the example computing environment of FIG. 1, and in accordance various aspects disclosed herein.

FIGS. 3A and 3B illustrate a GPU thread matching and CPU inter-transactional update sequence, in accordance with various aspects disclosed herein.

FIG. 4 illustrates a final compressed block structure resulting, in part, from the iterative GPU thread matching and CPU inter-transactional update sequence of FIGS. 3A-3C, in accordance with various aspects disclosed herein.

FIG. 5 illustrates an example optimization implantation to concurrently calculate maximal compression and fit for multiple sequential GPU instances.

FIG. 6 illustrates an example method for massively parallel data compression, in accordance various aspects disclosed herein.

### DETAILED DESCRIPTION

As previously mentioned, conventional data compression algorithms suffer from several drawbacks. For example, a representative conventional data compression technique is the Lempel-Ziv (LZ) family of data compressors. These LZ compressors are generally algorithmic mechanisms for universal lossless data compression based upon learned patterns within a data-block, generically referred to as dictionary encoders. These conventional algorithms are also the basis for common file extensions such as .ZIP or images extensions like. PNG or .GIF.

Broadly speaking, LZ compressors achieve compression by replacing repeated sequences of data with references and length tuples to allow for copy commands during decompression. In this manner, reiterated data later in files can be recreated by referencing the original occurrences (known as the distance or offset) early in the file and copying forward length numbers of bytes. This reduces space consumed as reference distance and copy length tuples are small relative to the associated sequences of data.

Traditionally, LZ-type compressors incorporate a sliding search window to spot potential matches. The data encoder may keep this window reference and iteratively compare the current end of file sequences with sequences present within the window representing prior data within the compressed data block. This reverse order compression and decompression ensures that back-references within the data block remain valid, such that as the data block is decompressed, the data block is reconstructed from the beginning and back-references become valid as they are retrieved.

Of course, not all data sequences within a data block may recur more than once, and such unique data sequences are commonly referenced as literals. Literals are often clustered at the beginning of the data block as there are fewer characters earlier in the file for which to generate a match. As literals do not repeat within a data block, literals must be included as-is within the data block during compression/decompression, and are frequently represented in the form of entropy encoding to reduce the space of these uncompressible characters.

In any event, these LZ-style compressors and other conventional compression techniques frequently suffer from the compression speed/ratio trade-off discussed above. These issues are greatly diminished by the use of multithreaded and single instruction multiple data (SIMD) architectures on the CPU; however no such massively parallel implementations exist today. Thus, in order to alleviate these, and other, problems, the present disclosure provides massively parallel, GPU-based data compression implementations that improve data compression speed while still achieving high data compression ratios.

More specifically, the techniques of the present disclosure include performing a full window search for a greatest repeat sequence in a single GPU transaction per encoded reference tuple. Through massively parallel programming, the search depth for recurrences is no-longer tied to the number of CPU search transactions, as the entire window may be simultaneously searched with a single GPU transaction per encoding reference tuple. Thus, the longer the repeat sequences present within the data block, regardless of their location within the search window, the faster the compression is achieved. Moreover, this full window search occurs while simultaneously achieving significantly higher compression ratios than conventional techniques by identifying the optimal reference. Consequently, the techniques disclosed herein minimize and/or eliminate the data compression time/ratio inverse correlation law associated with conventional data compression techniques.

Furthermore, due to the identification of optimal references, which are often (but not necessarily) the longest length reference, decompression speeds are correspondingly increased as well. This is because, during decompression, longer reference sequences result in less individual copy transactions by the CPU and longer more efficient copy transactions. Thus, a more optimal selection of reference tuples during compression improves subsequent decompression efficiency.

Thus, in accordance with the discussions herein, the present disclosure includes improvements to other technologies or technical fields at least because the present disclosure describes or introduces improvements in the field of digital data compression. Namely, the encoding module executing on the user computing device or other computing devices (e.g., external server) improves the field of digital data compression by increasing the speed and resulting compression ratio of data compression in a manner that was previously unachievable using conventional techniques. This improves over conventional techniques at least because such techniques lack the ability to perform the rapid, efficient data compression performed as a result of the instructions included in the encoding module, and are otherwise simply not capable of performing data compression in a manner similar to the techniques of the present disclosure.

In addition, the present disclosure includes specific features other than what is well-understood, routine, conventional activity in the field, or adding unconventional steps that confine the claim to a particular useful application, e.g., establishing, by the one or more processors, a global offset at a first data of the data file; substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence; determining, by the one or more processors, an optimal data sequence that minimizes non-matched data and maximizes matched data, the optimal data sequence corresponding to the first data sequence from the respective data sequences; storing, by the one or more processors, the optimal data sequence in a reference table; updating, by the one or more processors, the global offset based on the optimal data sequence; and/or iteratively performing these steps until the global offset is a beginning or an end of the data file, among others.

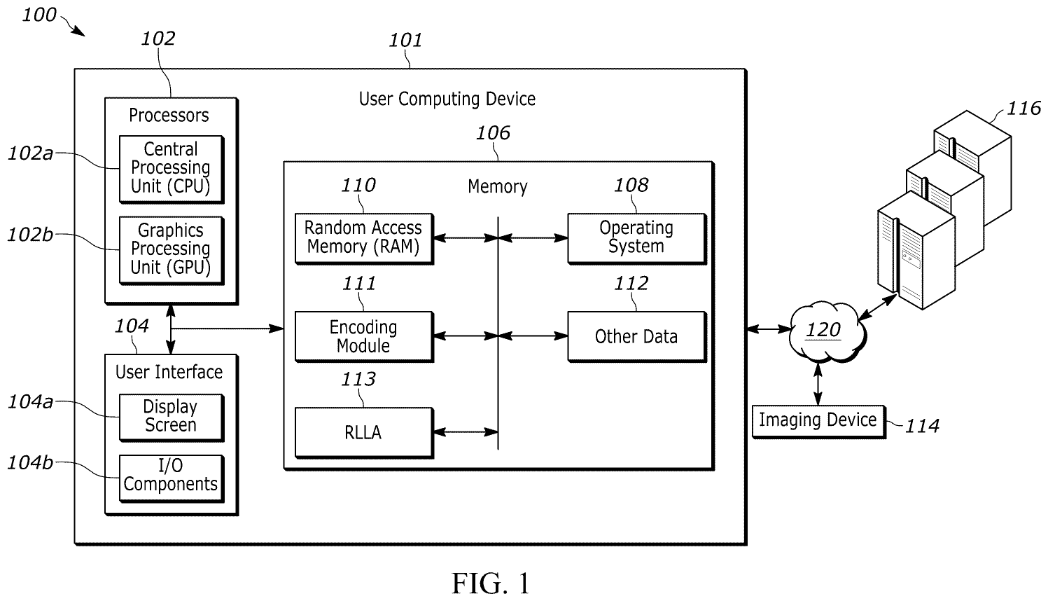

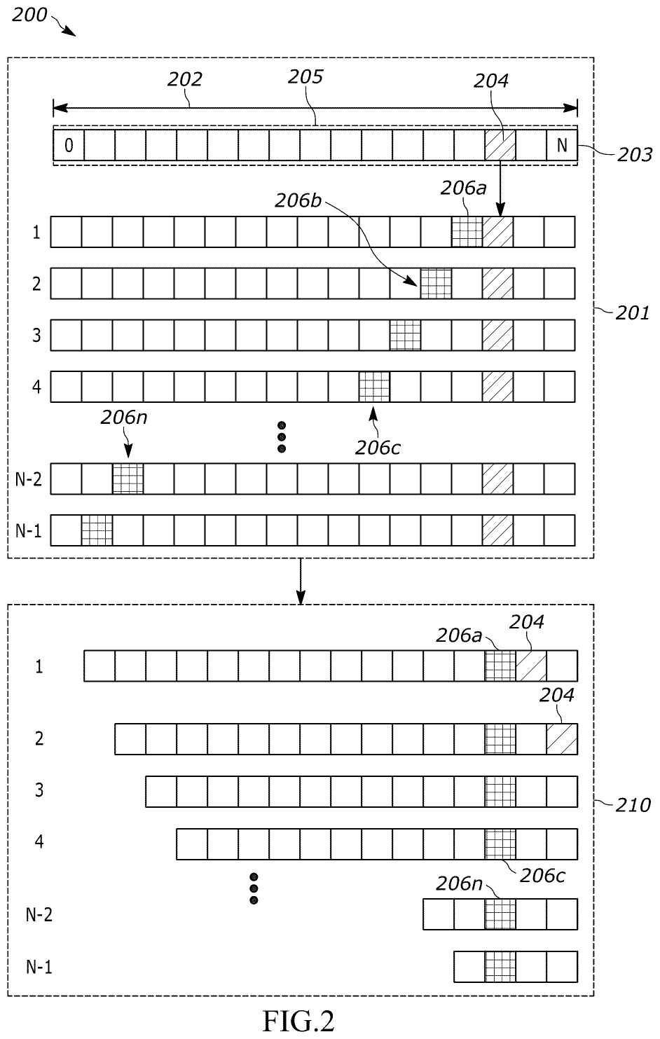

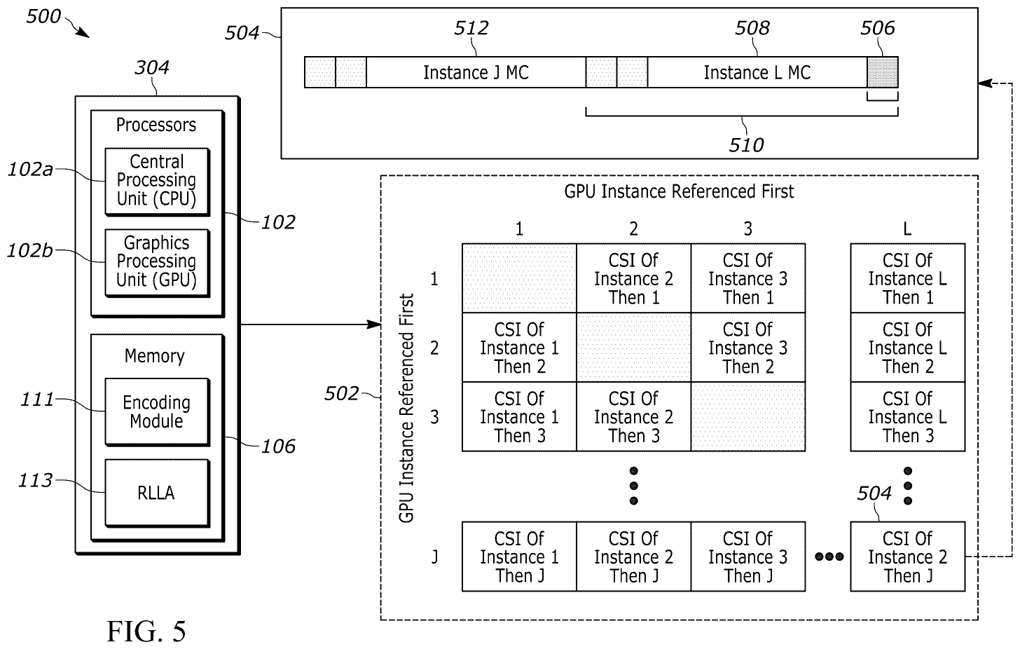

Regardless, and to provide a general understanding of the system(s)/components utilized in the techniques of the present disclosure, FIG. 1 illustrates an example computing environment for massively parallel data compression, in accordance various aspects disclosed herein. Thereafter, FIGS. 2-5 illustrate example mappings and workflows for performing massively parallel data compression. Finally, FIG. 5 illustrates an example method for massively parallel data compression, in accordance various aspects disclosed herein.

Further, as referenced herein, data locations within an indexed mapping may include bytes of data, bits of data, and/or any other suitable data symbol comprised of a quantity of data (e.g., bit encoded nucleic acid base-pairs, KB, MB, GB, TB, etc.) that may be included as part of a data file. Additionally, the data contained at each data location may be referenced herein, for example, as “symbol(s)”, “byte(s)”, and/or “bit(s)”. Accordingly, references to a byte of data when discussing a data location within a data file may be for ease of discussion only. Moreover, each reference herein to a GPU thread or other processor may be or include one or more shader implementations/SIMD “Lanes” /GPU threads/GPU “Warps/Waves” per data entry index, such that an entire input data sequence to be analyzed may be performed in a single or multiple GPU transactions of one or more GPU threads relative to other locations within the data file.

As mentioned, FIG. 1 illustrates an example computing environment 100 for massively parallel data compression, in accordance various aspects disclosed herein. As illustrated in FIG. 1, the example computing environment 100 may include a user computing device 101 that includes a processor 102, a user interface 104, and a memory 106. The processor 102 may have a central processing unit (CPU) 102a and a graphics processing unit (GPU) 102b. Generally speaking, both the CPU 102a and the GPU 102b may access the memory 106 to execute instructions included therein, such as the operating system 108, the encoding module 111, and/or to access data or instructions stored in the random-access memory (RAM) 110 and/or included in the other data 112. The CPU 102a may be configured to execute a wide range of tasks stored in the memory 106, such as determining which matching sequence is a longest data sequence, recording the position and length of the longest data sequence in a references and literal lengths array (RLLA) 113. The GPU 102b may be configured to perform tasks associated with searching for the longest data sequence within a data file, such as by comparing respective data sequences with a first data sequence, wherein each respective data sequence is offset from every other respective data sequence and the first data sequence. Of course, it should be understood that the CPU 102a and the GPU 102b may perform additional tasks not described herein. Further, it should be appreciated that the example computing environment 100 is merely an example and that alternative or additional components are envisioned.

The user computing device 101 further includes a user interface 104 configured to present/receive information to/from a user. As shown in FIG. 1, the user interface 104 may include a display screen 104a and I/O components 104b (e.g., ports, capacitive or resistive touch sensitive input panels, keys, buttons, lights, LEDs). According to some aspects, a user may access the user computing device 101 via the user interface 104 to review outputs from the processors 102 (e.g., executing the encoding module 111), upload/open a new data file, schedule a new data file for compression by the processors 102 executing the encoding module 111, make various selections, and/or otherwise interact with the user computing device 101 and the example computing environment 100. As discussed further herein, the processors 102 may receive an indication of a new data file, and may respond accordingly by executing instructions included as part of the encoding module 111 to compress the data file and update the RLLA 113 with length values and reference values corresponding to various data sequences.

Generally speaking, and as discussed further herein, the encoding module 111 may instruct various threads of the GPU 102b to analyze an input data file from a back/end of the data file to a front/beginning of the data file with a plurality of individual offsets relative to a global offset. The global offset may broadly represent how far into the data file the GPU 102b has managed to compress the data file at any given point during the compression sequence. The individual offsets may represent a particular byte that is a respective distance away from the global offset where a respective individual thread may begin to compare data sequences relative to the data sequence beginning adjacent to the global offset. More specifically, the encoding module 111 may also include instructions that cause the GPU 102b threads to iteratively search through the data file beginning at each respective individual offset to identify a longest non-matching data sequence that has no common symbols corresponding to the data sequence at the global offset and/or matching data sequence that is identical to a corresponding length data sequence beginning at the global offset. When the longest non-matching and/or matching data sequence is identified the encoding module 111 may instruct the GPU 102b threads to perform the search again based on a new global offset that is shifted relative to the prior global offset by the length value of the optimal matching data sequence, comprising reference tuples and/or literals. Accordingly, the encoding module 111 may cause the GPU 102b threads to iteratively perform such a search until the global offset reaches the beginning of the data file.

The memory 106 may store an operating system 108 capable of facilitating the functionalities as discussed herein, the RAM 110, the encoding module 111, as well as other data 112. The other data 112 may include a set of applications configured to facilitate the functionalities as discussed herein, and/or may include other relevant data, such as display formatting data, etc. It should be appreciated that one or more other applications are envisioned. Moreover, it should be understood that any processor (e.g., processor 102), user interface (e.g., user interface 104), and/or memory (e.g., memory 106) referenced herein may include one or more processors, one or more user interfaces, and/or one or more memories.

In any event, the memory 106 may include one or more forms of volatile and/or non-volatile, fixed and/or removable memory, such as read-only memory (ROM), electronic programmable read-only memory (EPROM), the RAM 110, the video random access memory (VRAM) 109, erasable electronic programmable read-only memory (EEPROM), and/or other hard drives, flash memory, MicroSD cards, and others.

In certain embodiments, the example computing environment 100 may also include an imaging device 114 that is configured to capture image data that, for example, may be compressed by the user computing device 101. As an example, the image data may represent tissue samples that are mounted on slides, and the imaging device 114 may be configured to capture multiple images of the tissue sample at multiple resolutions. The imaging device 114 may then upload and/or otherwise transfer the images to the user computing device 101 across the network 120 for compression. The user computing device 101 may receive the image data, and may proceed to compress the images in accordance with the instructions included as part of the encoding module 111.

Moreover, in some aspects, the example system 100 may perform the functionalities as discussed herein as part of a “cloud” network or may otherwise communicate with other hardware or software components within the cloud to send, retrieve, or otherwise analyze data. Thus, it should be appreciated that the example computing environment 100 may be/include a distributed cluster of computers, servers, machines, or the like. In this implementation, a user may utilize the distributed example computing environment 100 as part of an on-demand cloud computing platform. Accordingly, when the user interfaces with the example computing environment 100 (e.g., by requesting compression/decompression of a data file, uploading captured images to the user computing device 101 from the imaging device 114), the example computing environment 100 may actually interface with one or more of a number of distributed computers, servers, machines, or the like, to facilitate the described functionalities.

For example, the user computing device 101 may communicate and interface with an external server 116 via a network(s). The external server 116 may be, for example, a remote storage location for the compressed/uncompressed data files, and may receive the compressed data files from the user computing device 101 and/or data files directly from the imaging device 114. A user may interface with the user computing device 101 and may request decompression of a data file that was previously compressed by the processors 102 of the device 101. The user computing device 101 may then retrieve the compressed data file from the external server(s) 116, and may proceed to decompress the compressed data file, in accordance with the instructions included as part of the encoding module 111.

Further in these aspects, the network(s) used to connect the user computing device 101 to the imaging device 114 and/or the external server 116 may support any type of data communication via any standard or technology (e.g., GSM, CDMA, TDMA, WCDMA, LTE, EDGE, OFDM, GPRS, EV-DO, UWB, Internet, IEEE 802 including Ethernet, WiMAX, Wi-Fi, Bluetooth, and others). Moreover, the imaging device 114 and/or the external server 116 may include a memory as well as a processor, and the memory may store an operating system capable of facilitating some/all of the functionalities as discussed herein.

Additionally, it is to be appreciated that a computer program product in accordance with an aspect may include a computer usable storage medium (e.g., standard RAM, an optical disc, a universal serial bus (USB) drive, or the like) having computer-readable program code embodied therein, wherein the computer-readable program code may be adapted to be executed by the processor(s) 102 (e.g., working in connection with the operating system 108) to facilitate the functions as described herein. In this regard, the program code may be implemented in any desired language, and may be implemented as machine code, assembly code, byte code, interpretable source code or the like (e.g., via Golang, Python, Scala, C, C++, Java, Actionscript, Objective-C, Javascript, CSS, XML). In some aspects, the computer program product may be part of a cloud network of resources.

FIG. 2 illustrates an exemplary relative index mapping 200 performed by components of the example computing environment 100 of FIG. 1, and in accordance various aspects disclosed herein. For example, the processors 102 (e.g., GPU 102b) executing instructions included as part of the encoding module 111 may perform the actions and/or other functions illustrated by the exemplary relative index mapping 200 of FIG. 2. Of course, it should be appreciated that any of the actions described in reference to FIG. 2 may be performed by and/or may require the use of any suitable components of the example computing environment 100 and/or other suitable components not shown therein or combinations thereof.

Generally speaking, the exemplary relative index mapping 200 represents the locations of individual offsets relative to the global offset at any particular iteration of the data compression sequence, as described herein. Utilizing these individual offsets, the processors (e.g., GPU 102b threads) may search through the data file to identify matching and non-matching data sequences between the data sequence extending toward the beginning of the data file from the global offset and a data sequence extending toward the beginning of the data file from each individual offset. As illustrated in FIG. 2, the exemplary relative index mapping 200 includes a global offset-aligned index mapping 201 and an individual offset-aligned index mapping 210.

The global offset-aligned index mapping 201 and the individual offset-aligned index mapping 210 represent the index mapping performed by the processors of the present disclosure as part of searching the data file for matching data sequences. In particular, the global offset-aligned index mapping 201 and the individual offset-aligned index mapping 210 include a data file of size N (e.g., the data file has N bytes of data), as represented by the reference line 202, such that each individual block within the data file represents a byte of data. As illustrated in FIG. 2, both the global offset-aligned index mapping 201 and the individual offset-aligned index mapping 210 include a global offset 204 and a respective individual offset 206a-n. The global offset 204 may indicate a last byte compressed by the processors as part of the data compression sequence, described herein, and each box to the right of the global offset 204 (e.g., as part of a compressed portion 203) represents a previously processed byte of the data file. The processors may calculate the instance offsets 206a-n by determining an instance number offset from the global offset 204 in a direction of the beginning of the data file and/or based on any suitable variably sized data window within the data file.

More specifically, the processors of a user computing device may establish a processing window of size N bytes (e.g., represented by the reference line 202) that may include the entire data file to be compressed. The number of bytes (N) defining the processing window size may also be the approximate number of concurrent GPU worker threads (e.g., of GPU 102b) that may be dispatched to perform the compression sequence analysis, as described herein. All of these N GPU threads may not necessarily execute simultaneously on the GPU based on the number and size of GPU work-groups, but the processors may delay queueing a new transaction (e.g., performing a subsequent iteration of the compression sequence analysis) until all GPU thread instances complete their respective analysis tasks to establish the next global offset (e.g., global offset 204). In certain embodiments, the processors may also reference a pre-defined dictionary of commonly encountered data sequences that may be stored in memory (e.g., memory 106, external server 116) while performing the compression sequence analysis.

Further, as illustrated in FIG. 2, each GPU thread is provided with the current global offset 204, which indicates the current location within an input buffer that the GPU threads may compare for potential repeat patterns with the data sequence at the global offset 204. Thus, the global offset 204 represents the current active compression symbol location. In many instances, the global offset 204 may represent a byte/data location within the data file, but in certain embodiments, the global offset 204 may represent other types of symbols as well. Each GPU thread is also provided with an instance offset 206a-n, which may be specific to each particular thread/shader instance, and the instance offset 206a-n index may generally be between 1 and N (e.g., instance offset 206a-n∈[1,N)). The instance offset 206a-n broadly defines a degree/distance by which the comparison window for the respective GPU thread is shifted relative to the reference window, which typically corresponds to the global offset 204. However, in certain embodiments, the comparison window may be another location earlier within the data file, and/or may alternatively represent a known symbol dictionary or a symbol lookup tree. If, for example, the comparison window represents a symbol dictionary or lookup tree, the instance offset 206a-n may represent a symbol offset in the corresponding lookup table or tree.

In any event, the global offset-aligned index mapping 201 and the individual offset-aligned index mapping 210 may illustrate an intermediate compression iteration of the compression sequence, and as a result, the data file may have a compressed portion 203 the includes the byte representing the global offset 204 and extends to the end of the data file (e.g., byte N in the compressed portion 203), as well as an uncompressed portion 205 that includes the bytes representing the individual offsets 206a-n extending to the beginning of the data file (e.g., byte 0 in the uncompressed portion 205). The compressed portion 203 may be a portion of the data file that has already been analyzed by the processors, in accordance with the instructions included as part of the encoding module 111, and may thereby have reference location values and/or length values included in an RLLA table (e.g., RLLA 113). By contrast, the uncompressed portion 205 may be a remaining portion of the data file that has not yet been analyzed by the processors, in accordance with the instructions included as part of the encoding module 111, and may thereby not have reference location values and/or length values included in the RLLA table.

As illustrated in FIG. 2, the global offset-aligned index mapping 201 includes index mappings for a plurality of GPU threads (e.g., GPU thread 1, GPU thread 2, . . . , GPU thread N-2, GPU thread N-1) that are aligned relative to the global offset 204. Each GPU thread includes an individual offset 206a, 206b, 206c, 206n that is offset from the global offset 204. For example, the individual offset 206a is offset from the global offset by one position within the data sequence, the individual offset 206b is offset from the global offset by two positions within the data sequence, the individual offset 206c is offset from the global offset by four positions within the data sequence, and the individual offset 206n is offset from the global offset by X positions within the data sequence, wherein X corresponds to a distance from the global offset to the N-2 position relative to the end of the data file. Each GPU thread may compare data sequences beginning at the respective individual offset 206a-n locations and extending toward the beginning of the data file (e.g., the uncompressed portion 205) with the data sequence beginning at the global offset 204 and extending toward the beginning of the data file.

The individual offset-aligned index mapping 210 represents an alternative visualization of the index mapping performed by the processors of the present disclosure as part of searching the data file for matching data sequences. Namely, the individual offset-aligned index mapping 210 illustrates the index mappings for a plurality of GPU threads (e.g., GPU thread 1, GPU thread 2, . . . , GPU thread N-2, GPU thread N-1) that are aligned relative to the individual offsets 206a-n. Thus, in this mapping 210, the individual offsets 206a-n are aligned while the global offset 204 adjusts for each GPU thread. In any event, the index mapping represented by the individual offset-aligned index mapping 210 may represents an identical compression sequence as the global offset-aligned index mapping 201, such that the alternative mappings 201, 210 are included for the purposes of discussion/clarity only. The processors are configured to evaluate the data sequences beginning at the respective individual offset 206a-n locations and extending toward the beginning of the data file (e.g., the uncompressed portion 205) with the data sequence beginning at the global offset 204 and extending toward the beginning of the data file.

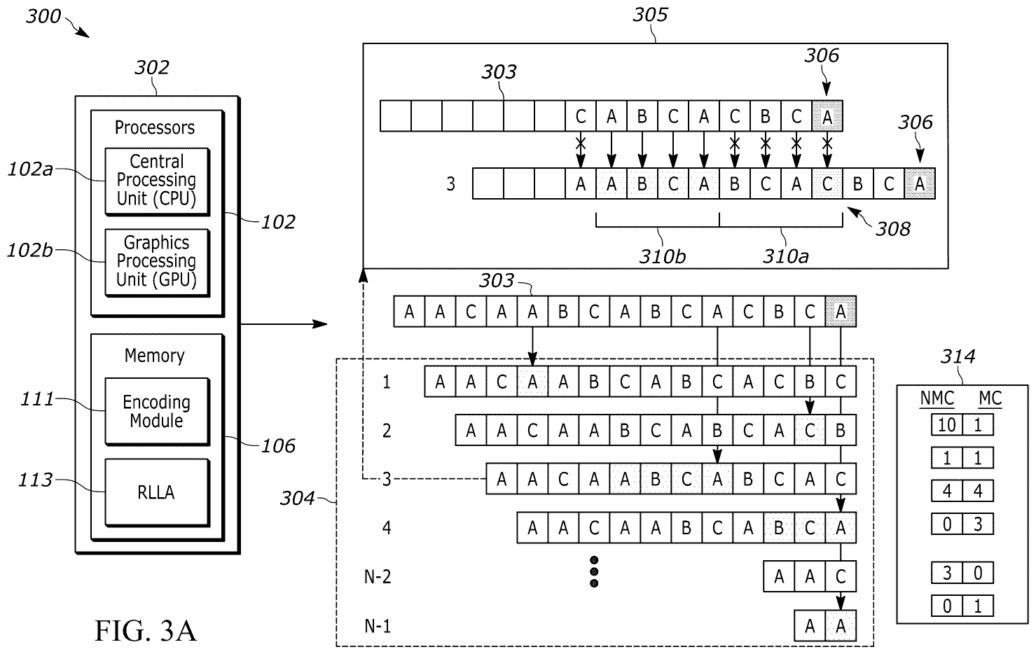

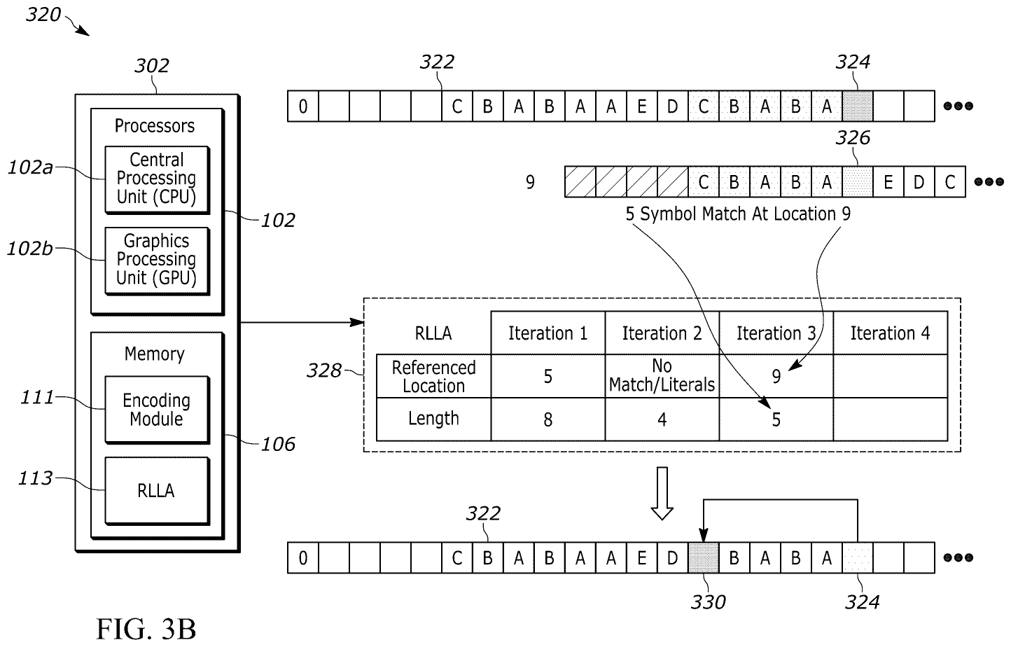

FIGS. 3A and 3B illustrate a GPU thread matching and CPU inter-transactional update sequence, in accordance with various aspects disclosed herein. In particular, FIG. 3A illustrates a GPU thread matching sequence 300, wherein the processors 102 of the user computing device 304 may match data sequences of a data file as part of a data compression sequence. The processors 102 may assign and/or otherwise match individual GPU 102b threads to individual, indexed mappings of the data file, as illustrated in the first mappings block 304 of FIG. 3A. During a single iteration of the matching sequence 300, each GPU 102b thread (e.g., GPU thread 1, 2, 3, . . . , N-2, N-1) may evaluate the individual, indexed mappings to generate matching sequences with the global-indexed mapping 303. When the processors 102 identify an optimal matching data sequence at the end of any individual iteration of the matching sequence 300, the processors 102 may store the non-matching count (NMC) and/or a matching count (MC) corresponding to the thread sequence (and matching data sequence contained therein), and may advance the global offset 306 towards the beginning of the data file by the length of the NMC and/or the MC.

More specifically, the GPU 102b threads may compare the data/symbols (e.g., bytes) in the respective individual offset-indexed mappings to the global-indexed mapping 303 (e.g., reference) sequence of data/symbols to be compressed. The GPU 102b threads may compare the data at each data location subsequently decrement the respective indices working backwards towards the beginning of the input data file or reference sequence. In particular, the NMC may be decremented and recorded relative to the instance offset relative to the global offset within the data buffer, and the GPU 102b may continue this counting as long as the data within the comparison window does not match the corresponding reference data in the global-indexed mapping 303. The GPU 102b may stop counting the NMC when a data entry is found to match the reference byte stream in the global-indexed mapping 303.

At this point, the GPU 102b may record the NMC and being establishing the MC by counting the number/amount of data/symbols that match the reference sequence in the global-indexed mapping 303, starting from the stopping point of the NMC. When a data entry fails to match the reference sequence in the global-indexed mapping 303, the GPU 102b MC process is complete, and the GPU 102b may record the number of “matches” as the MC. As a result of this match counting, the GPU 102b threads may output both the NMC and the MC during each iteration of the matching sequence 300, as illustrated in FIG. 3A. As discussed further herein, these NMC and MC values may be transferred back to the CPU 102a for optimal selection of a matching data sequence or the NMC and MC values may be analyzed in parallel for optimal selection on the GPU 102b. Furthermore, the individual GPU 102b threads may record the number of proximal NMC and MC specific to their data entries in each respective individual offset-indexed mapping in a library of predetermined byte sequences or lookup tree of byte sequences.

In order to generate the matching sequences, the individual GPU 102b threads may compare the data at each individual data location (e.g., byte of data) of the individual, indexed mappings to corresponding data locations of the global-indexed mapping 303. For example, a first GPU 102b thread may compare data in the first individual offset-indexed mapping (e.g., thread 1 illustrated at the top of the first mappings block 304) represented at the first data location (e.g., C) with corresponding data represented at the same indexed location in the global-indexed mapping 303 (e.g., A). In other words, the “C” data at the first data location in the first individual offset-indexed mapping and the “A” data at the first data location in the global-indexed mapping 303 have an identical index (e.g., 0 or 1, representing an initial data location within the respective sequences), such that the first GPU 102b thread recognizes that the data in these particular locations of the respective mappings should be compared to determine potential matches. In this example, the data in these respective data locations may not match (e.g., C=/=A), such that the first GPU 102b thread may continue comparing the data at each data location in the first individual offset-indexed mapping with the data at the corresponding data locations in the global-indexed mapping 303 to determine potential matches.

This matching sequence is detailed in the second mappings block 305, where the third GPU 102b thread performs matching between the individual data locations in the index mapping based on the third individual offset and the global-indexed mapping 303. As illustrated in the second mappings block 305, the third GPU 102b thread may compare the data in the global-indexed mapping 303 with the third individual offset-indexed mapping by comparing data in both mappings that is shifted by three data locations. Namely, the first data location in the third individual offset-indexed mapping is three data locations towards the beginning of the data file relative to the first data location in the global-indexed mapping 303. This is illustrated in FIG. 3A by the third GPU 102b thread evaluating the third individual offset-indexed mapping skipping a comparison of the global offset 306 and two subsequent data locations with data contained in the global-indexed mapping 303. Instead, the third GPU 102b thread begins this iteration of the matching sequence 300 by comparing the data in the data location represented by the third individual offset 308 with the data in the data location represented by the global offset 306.

As illustrated in the second mappings block 305, the third GPU 102b thread may determine that there are no matches between the data in the first four data locations 310a of the third individual offset-indexed mapping with the data in the corresponding data locations of the global-indexed mapping 303. However, the third GPU 102b thread may determine that the second four data locations 310b each contain data (e.g., A, B, C, A) that matches with the data included in the corresponding data locations of the global-indexed mapping 303. The third GPU 102b thread may track the length (e.g., 4) and location (e.g., extending from the fifth data location to the eighth data location) of the matching sequence in the second four data locations 310b. The thread may then terminate when the subsequent byte following 310b ‘A’, at the ninth data location, no-longer matches the globally indexed mapping 303 ‘C’, at the ninth data location, such that the match sequence 310b may be completed.

When the third GPU 102b thread reaches the end of the match sequence 310b, the thread may return the matching sequence and/or the non-matching sequence 310a identified during this iteration of the matching sequence 300. In certain instances, a GPU 102b thread may compare stored MC length/location matching data sequences for each 102b thread (e.g., GPU 102b threads 1, 2, 3, 4, . . . , N-2, N-1) to determine the optimal matching data sequence and/or may compare these values as the GPU 102b actively evaluates the respective mappings to find the optimal mapping configuration between the plurality of GPU threads.

With the matching sequences, the GPU 102b threads may report and/or otherwise communicate the number of non-matching characters (NMC) and matching characters (MC) for each thread in 314 to the CPU 102a for storage in the RLLA 113. Moreover, the CPU 102a and/or the GPU 102b may proceed to compare each of the longest matching data sequences from all of the individual offset-indexed mappings to determine a single, optimal matching data sequence as a result of this iteration of the matching sequence 300. For example, as illustrated in FIG. 3A, the GPU 102b threads may report in 314 NMC values of: 10, 1, 4, 0, . . . , 3, 0 and MC values of: 1, 1, 4, 3, . . . , 0, 1 for the corresponding individual offset-indexed mappings 1, 2, 3, 4, . . . , N-2, N-1.

However, in certain instances, the GPU 102b may not identify an immediate matching sequence (e.g., two or more sequential data entries/symbols with a no-match count (NMC) of 0) in any individual offset-indexed mapping. In these instances where no matching sequences are identified, GPU 102b and/or the CPU 102a may return/record a distance to a first match between the global-indexed mapping 303 a respective individual offset-indexed mapping (e.g., the first individual offset-indexed mapping). This first match may represent a matching data entry with the shortest distance between the global offset 306 relative to any other matching data entry. Accordingly, when no matching sequences are identified, the processors 102 may increment the global offset 306 by the distance between the global offset 306 and the first match, and the processors 102 may also store the intervening non-match count data entries as literals in the RLLA 113 and/or any other suitable location(s).

Thus, in the prior example, the CPU 102a and/or the GPU 102b may determine that the matching sequence from the fourth thread, i.e., locations zero to three relative to the global offset (‘BCA’) in the fourth row of 304, is the optimal matching data sequence because this matching sequence has the highest number of MC (e.g., 3) to NMC (e.g., 0) relative to the other longest matching sequences from the other individual offset-indexed mappings. However, in a different implementation and based upon other data within the file, the CPU 102a and/or GPU 102b may determine that the matching sequence represented by the second four data locations 310b from the third thread of 304 is the optimal matching data sequence. Accordingly, the non-matching sequence from the first four data locations 310a and the corresponding length and/or reference location values for the sequences may be recorded. Regardless, the offset-indexed mapping corresponding to MC and literals corresponding to NMC may be stored in the RLLA 113. Thus, the CPU 102a and/or the GPU 102b may proceed to store the decided upon optimal values in the RLLA 113, and as a result, these stored values may likely achieve the highest compression ratio/speed possible relative to the other matching/literal sequences from the other individual offset-indexed mappings.

The storing/recording of matching data sequences and/or literal sequences in the RLLA table may be generally referenced as a CPU inter-transactional update sequence. FIG. 3B illustrates such a CPU inter-transactional update sequence 320, wherein the processors 102 of the user computing device 304 may update the RLLA 113 when the GPU 102b threads have determined an optimal matching data sequence. In particular, the GPU 102b threads may evaluate the various individual offset-indexed mappings (e.g., as illustrated in FIG. 3A, and mapping 9 in FIG. 3B) to determine an optimal matching data sequence.

When the optimal matching data sequence is determined, the CPU 102a and/or the GPU 102b may record the matching data sequence in the RLLA 113, which includes referenced location values and length values that may represent the compressed data stream corresponding to the data file. Generally speaking, the matched reference location values and the length values represent the location and length of the matching sequence within the data file. The matched reference location value may correspond to the individual offset (relative to the current global offset) at which the longest matching sequence begins, such that during decompression, the processors 102 may back-reference the data file to determine the correct data sequence by copying the data sequence ending at the individual offset. Further, the length value may indicate the distance and/or number of data/symbols relative to the individual offset the processors 102 may need to copy when filling-in the data sequence ending at the current global offset.

For example, data file 322 includes a current global offset 324, and the GPU 102b threads may determine a longest matching data sequence at the individual offset 326 (e.g., represented by individual offset-indexed mapping 9), as part of a third iteration of the data matching/compression sequence. This longest matching sequence (e.g., “CBABA”) may include five data entries/symbols that extend from the individual offset 326 back towards the beginning of the data file 322. Thus, the GPU 102b thread may report this information to the CPU 102a, which may record the five data entry match at referenced location nine in the RLLA 113. This is illustrated in FIG. 3B, where the CPU 102a records the referenced location “9” and the length value “5” in the expanded RLLA 328 in a storage location designated for the third iteration of the data matching/compression sequence. The expanded RLLA 328 may correspond to the RLLA 113, and may include example reference location values and length values for ease of discussion only.

Alternatively, the reference location may reference the location of the data relative to the beginning of the data file/data block/or data lookup table. The longest matching sequence as mentioned before in 326 (e.g., “CBABA”), which may include five data entries/symbols that extend from the individual offset 326 back towards the beginning of the data file 322, may be encoded as the current global offset minus the individual offset 326 to give the number of bytes between the beginning of the file 322 and the individual offset 326. Thus, the RLLA table 328 “reference locations” may be represented in the form of global file offsets. This method may provide additional compression at the entropy encoding stage in data sequences with high global redundancies by referencing the earliest represented and frequently repeated sequence such that the initial “reference location” of such a repeated sequence has low overall entropy.

In any event, when the CPU 102a records the reference location value and/or the length value in the RLLA 113, 328, the processors 102 may then increment the global offset 324 to initiate a subsequent iteration of the data matching/compression sequence. Continuing the prior example, the processors 102 may increment the global index 324 by five data locations within the data file 322, and as a result, the new global index 330 may be five data locations closer to the beginning of the data file 322 relative to the global index 324. The processors 102 may then initiate a subsequent iteration of the data matching/compression sequence with the new global index 330 and may iteratively continue this process until the global index 324, 330 reaches zero (e.g., the global index corresponds to the first data location of the data file 322). Of course, the processors 102 may increment the global index 324 in this manner regardless of whether the longest matching data sequence is a matching sequence or a literal sequence.

In certain embodiments, the processors 102 may utilize a match length threshold, such that only matches exceeding a certain length value are considered valid. In these embodiments, the processors 102 may ignore data sequence matches with length values below the match length threshold in favor of entropy encoding literals, which may consume less memory space than matches shorter than the match length threshold. Moreover, in the event of two matches of equal length, the processors 102 may designate and/or otherwise record the matching sequence with a higher index in RLLA tables recording relative reference locations or the lower index in RLLA tables recording global reference locations. Higher index values may generally represent sequences occurring closer to the current global index, which may be more frequent under certain local redundant data sequences; whereas lower index values represent locations earlier in the data file 322, and thus may be more likely to represent a lower-entropy index with an opportunity to be referenced by a greater number of subsequent global indices during the encoding process in globally redundant files than the lower index sequences of equal length.

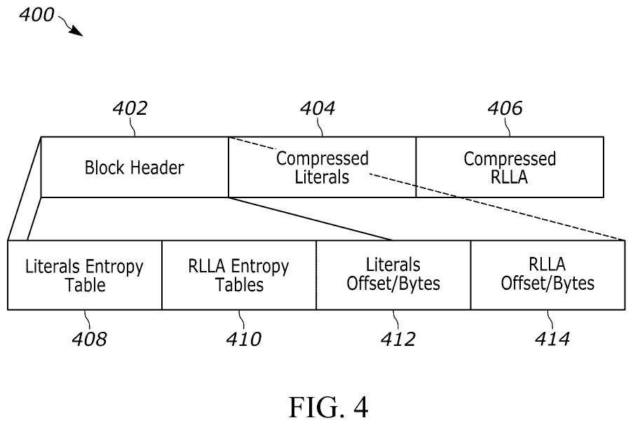

With the RLLA 113, 328 containing reference location values and length values for an entire data file, the processors 102 may generate a final compressed block structure. FIG. 4 illustrates an exemplary final compressed block structure 400 resulting, in part, from the iterative GPU thread matching and CPU inter-transactional update sequences of FIGS. 3A and 3B, in accordance with various aspects disclosed herein. Generally, the final compressed block structure 400 includes a block header 402, a compressed literals block 404, and a compressed RLLA block 406.

Generally, the block header 402 may contain all necessary information to decompress a data file. For example, the block header 402 may include a literals entropy table 408, an RLLA entropy table 410, a literals offset/bytes block 412, and an RLLA offset/bytes block 414. The literals offset/bytes block 412 may include bytes (e.g., offset and size) representing the compressed literals, the RLLA offset/bytes block 414 may include bytes (e.g., offset and size) representing the compressed RLLA table, and the literals entropy table 408 and RLLA entropy table 410 may be used to decode the byte sequences for both blocks 412, 414.

Specifically, the processors may compress the RLLA using any suitable compression/encoding technique, such as asymmetric numeral systems, other entropy compression techniques, and/or any other techniques or combinations thereof. The processors may also tabulate/calculate the referenced location values and length values from the RLLA, as well as generating any suitable symbol libraries for the entropy encoding techniques. The processors may also achieve greater compression relative to conventional techniques using dynamic counting routines for intelligently compressing literals and matching sequence references. Namely, the resulting compression ratio may greatly favor literals at the beginning of a data file due to a general lack of data from which to create references. By contrast, the resulting compression ratio may greatly favor matching sequence references later in the data file, as the processors have a significantly larger data block of sequences from which to create references relative to the beginning of the data file. Further, when using a data/symbol dictionary, references may be the dominant form of entry in the compression sequence. Literals may also be compressed (e.g., compressed literals block 404) using entropy encoding in a separate block at the beginning of the file.

As a result of these compression/encoding techniques, the entropy tables 408, 410 used for entropy encoding of literals and matching sequence references may be stored within the block header 402 located at the beginning of the final compressed block structure 400. The processors may also write the compressed literal block 404 and the compressed RLLA block 406 into the final compressed buffer, and the relative byte location (e.g., offset) and size of each block may also be stored in the literals offset/bytes block 412 and the RLLA offset/bytes block 414 in the block header 402.

However, in certain embodiments, the systems of the present disclosure may implement various optimization strategies that further improve the resulting compression ratio and/or compression speed. For example, FIG. 5 illustrates an example optimization implantation 500 to concurrently calculate a maximal compression and a maximum fit for two GPU instances reference tuples implemented sequentially. Generally speaking, the example optimization implantation 500 includes calculating and determining a maximum compression index score (CIS), an index defined as the combined minimal no-match and maximal match lengths by yielded by sequentially implementing reference tuples and literals for a multiple of GPU thread results together after single match run. In other words, the CIS represents a mathematical optimization of two or more GPU thread match regions fit within the no-match regions of another/other GPU threads to minimize the total no-match counts/literals. An example of one implementation of a CIS would be the subtraction of reference location and count of one GPU thread from the no-match count of another GPU thread.

For example, as illustrated in FIG. 5, the processors 102 may calculate various composite CISs by considering various combinations of sequential GPU 102b thread instances, represented in the CIS combination table 502. This calculation is more granularly illustrated for a representative GPU instance sequence 504 of GPU 102b thread L, which has a lower no-match count, then GPU 102b thread J, with a no-match count region 510 that completely includes all of the thread L match region 508. In other words, the GPU instance sequence 504 involves GPU 102b thread L (where L∈[1,N)) returning an instance L MC 508 and GPU 102b thread J (where J∈[1,N)) returning an instance J MC 512. To calculate the CIS for the GPU instance sequence 504, the processors 102 may subtract the residual NMC 510 length value of the GPU 102b instance J from the combined length values of the instance L MC 508 and the instance J MC 510. In the event that the sequential GPU 102b thread instances returned MCs with overlapping data/symbols, the processors 102 may also subtract the length value of such overlap from the combined length values of the instance L MC 508 and the instance J MC 510 to determine the CSI for the GPU instance sequence 504.

In certain embodiments, the CPU 102a or the GPU 102b may implement the optimization algorithm represented by the example optimization implantation 500. Moreover, as a result of the implantation 500 on the CPU 102a or GPU 102b, the example optimization implantation 500 may maximize the number of most proximal MCs relative to the most proximal NMCs and select one or more references to symbols within the uncompressed data stream to create an LZ-style compression reference and/or within a predetermined byte table or byte lookup tree.

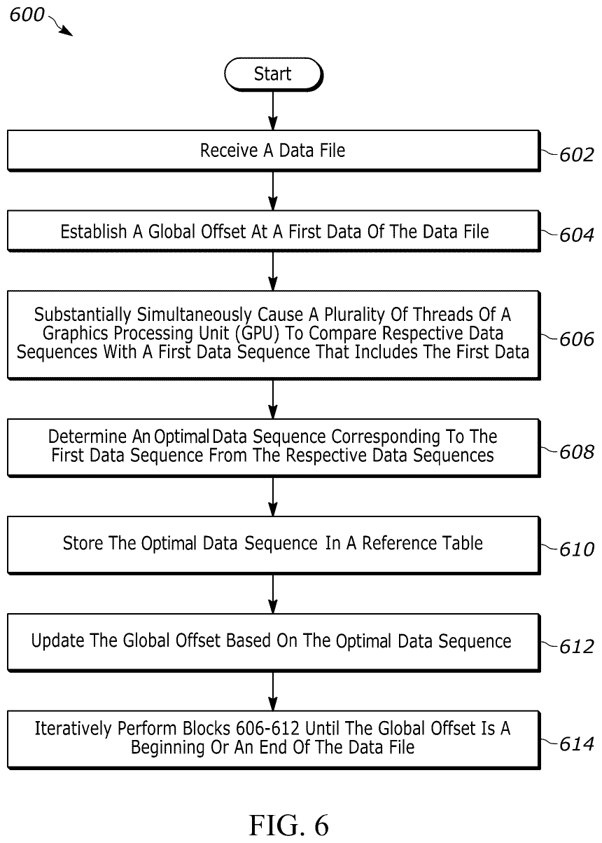

FIG. 6 illustrates an example method 600 for massively parallel data compression, in accordance with various aspects disclosed herein. For ease of discussion, many of the various actions included in the method 600 may be optional, and may be described herein as performed by or with the use of a processor (e.g., processor 102). However, it is to be appreciated that the various actions included in the method 600 may be performed by, for example, a specific processing unit (e.g., CPU 102a, GPU 102b) executing the encoding module 111, an external server (e.g., external server 116), and/or other suitable processors or combinations thereof.

The method 600 may include receiving a data file (block 602). The method 600 may further include establishing a global offset at a first data (e.g., data located at a first data location) of the data file (block 604). The method 600 may further include substantially simultaneously causing a plurality of threads of a GPU to compare respective data sequences with a first data sequence that includes the first data (block 606). Each thread of the plurality of threads may compare a respective data sequence of the respective data sequences, and each respective data sequence may be offset from every other respective data sequence and the first data sequence.

The method 600 may further include determining an optimal data sequence that minimizes non-matched data and maximizes matched data, wherein the optimal data sequence corresponds to the first data sequence from the respective data sequences (block 608). The method 600 may further include storing the optimal data sequence in a reference table (block 610). The method 600 may further include updating the global offset based on the optimal data sequence (block 612). The method 600 may further include iteratively performing the steps included in blocks 606-612 until the global offset is a beginning or an end of the data file (block 614).

In some embodiments, storing the optimal data sequence in the reference table may further comprise: storing (i) a reference location and (ii) a length value of the optimal data sequence in the reference table.

In certain embodiments, the optimal data sequence may include (i) a reference sequence or (ii) a literal sequence. Further in these embodiments, the method 600 may further comprise: responsive to determining that the optimal data sequence is a literal sequence, storing the length of the literal sequence and a reference location of the literal sequence in a literal table.

In some embodiments, the data file may include image data. In certain embodiments, the number of threads corresponding to the plurality of threads may equal a number of bytes in the data file.

In certain embodiments, the method 600 may further comprise: receiving, after the actions represented at block 614, a search query to identify a feature represented in the data file; and searching the data file based on the reference table.

In some embodiments, the global offset may be a first global offset, and updating the first global offset based on the optimal data sequence may further comprise: establishing a second global offset at a first data location within the data file that is a distance from the first global offset represented by a length value of the optimal data sequence.

In certain embodiments, the method 600 may further comprise: calculating an offset value and a length value for each data sequence in the reference table; and compressing the reference table using an entropy encoding sequence (e.g., asymmetric numeral systems (ANS)).

In some embodiments, the method 600 may further comprise: determining that at least two data sequences with length values corresponding to the optimal data sequence are generated by two different threads of the plurality of threads; determining that a first data sequence of the at least two data sequences has a higher index value than a second data sequence of the at least two data sequences; and storing the first data sequence in the reference table.

In certain embodiments, the method 600 may further comprise: storing, by the one or more processors at step (g), a reference representing a location of the first data sequence relative to (i) the beginning of the data file or (ii) the global offset.

In certain embodiments, the method 600 may further comprise: comparing a length value of the optimal data sequence with a match length threshold value; responsive to determining that the length value does not exceed the match length threshold value, determining a second longest data sequence; and responsive to determining that a second length value of the second longest data sequence exceeds the match length threshold value, storing the second longest data sequence in the reference table.

In some embodiments, the method 600 may further comprise: at each iteration of the actions represented by blocks 606-612, calculating a compression index score for each thread of the plurality of threads by subtracting a respective number of non-matching characters from a respective number of matching characters; and determining a maximum compression index score from the compression index score for each thread of the plurality of threads.

In certain embodiments, the method 600 may further comprise: calculating a combined compression index score for each respective pair of threads from the plurality of threads by subtracting a number of overlapping matching characters and a number of residual non-matching characters from a combined number of matching characters; and determining a maximum combined compression index score from the combined compression index score for the each respective pair of threads of the plurality of threads.

### ASPECTS OF THE PRESENT DISCLOSURE

1. A computer-implemented method for massively parallel data compression, the method comprising: (a) receiving, at one or more processors, a data file; (b) establishing, by the one or more processors, a global offset at a first data of the data file; (c) substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence; (d) determining, by the one or more processors, an optimal data sequence that minimizes non-matched data and maximizes matched data, the optimal data sequence corresponding to the first data sequence from the respective data sequences; (e) storing, by the one or more processors, the optimal data sequence in a reference table; (f) updating, by the one or more processors, the global offset based on the optimal data sequence; and (g) iteratively performing steps (c)-(f) until the global offset is a beginning or an end of the data file.

2. The computer-implemented method of aspect 1, wherein storing the optimal data sequence in the reference table further comprises: storing, by the one or more processors, (i) a reference location and (ii) a length value of the optimal data sequence in the reference table.

3. The computer-implemented method of any of aspects 1-2, wherein the optimal data sequence includes (i) a reference sequence or (ii) a literal sequence.

4. The computer-implemented method of aspect 3, further comprising: responsive to determining that the optimal data sequence is a literal sequence, storing the length of the literal sequence and a reference location of the literal sequence in a literal table.

5. The computer-implemented method of any of aspects 1-4, wherein the data file includes image data.

6. The computer-implemented method of any of aspects 1-5, wherein the number of threads corresponding to the plurality of threads equals a number of bytes in the data file.

7. The computer-implemented method of any of aspects 1-6, further comprising: receiving, by the one or more processors and after step (g), a search query to identify a feature represented in the data file; and searching, by the one or more processors, the data file based on the reference table.

8. The computer-implemented method of any of aspects 1-7, wherein the global offset is a first global offset, and updating the first global offset based on the optimal data sequence further comprises: establishing a second global offset at a first data location within the data file that is a distance from the first global offset represented by a length value of the optimal data sequence.

9. The computer-implemented method of any of aspects 1-8, further comprising: calculating, by the one or more processors, an offset value and a length value for each data sequence in the reference table; and compressing, by the one or more processors, the reference table using an entropy encoding algorithm.

10. The computer-implemented method of any of aspects 1-9, further comprising: storing, by the one or more processors at step (g), a reference representing a location of the first data sequence relative to (i) the beginning of the data file or (ii) the global offset.

11. The computer-implemented method of any of aspects 1-10, further comprising: comparing, by the one or more processors, a length value of the optimal data sequence with a match length threshold value; responsive to determining that the length value does not exceed the match length threshold value, determining, by the one or more processors, a second optimal data sequence; and responsive to determining that a second length value of the second optimal data sequence exceeds the match length threshold value, storing, by the one or more processors, the second optimal data sequence in the reference table.

12. The computer-implemented method of any of aspects 1-11, further comprising: at each iteration of steps (c)-(f), calculating, by the one or more processors, a compression index score for each thread of the plurality of threads by subtracting a respective number of non-matching characters from a respective number of matching characters; and determining, by the one or more processors, a maximum compression index score from the compression index score for each thread of the plurality of threads.

13. The computer-implemented method of any of aspects 1-12, further comprising: calculating, by the one or more processors, a combined compression index score for each respective pair of threads from the plurality of threads by subtracting a number of overlapping matching characters and a number of residual non-matching characters from a combined number of matching characters; and determining, by the one or more processors, a maximum combined compression index score from the combined compression index score for the each respective pair of threads of the plurality of threads.

14. A system for massively parallel data compression, comprising: a memory storing a set of computer-readable instructions; and one or more processors interfacing with the user interface and the memory, and configured to execute the set of computer-readable instructions to cause the one or more processors to: (a) receive a data file, (b) establish a global offset at a first data of the data file, (c) substantially simultaneously cause a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence, (d) determine an optimal data sequence corresponding to the first data sequence from the respective data sequences, (e) store the optimal data sequence in a reference table, (f) update the global offset based on the optimal data sequence, and (g) iteratively perform steps (c)-(f) until the global offset is a beginning or an end of the data file.

15. The system of aspect 14, wherein the instructions, when executed, further cause the one or more processors to store the optimal data sequence in the reference table by: storing (i) a reference location and (ii) a length value of the optimal data sequence in the reference table.

16. The system of any of aspects 14-15, wherein the optimal data sequence includes (i) a reference sequence or (ii) a literal sequence, and wherein the instructions, when executed, further cause the one or more processors to: responsive to determining that the optimal data sequence is a literal sequence, store the length of the literal sequence and a reference location of the literal sequence in a literal table.

17. The system of any of aspects 14-16, wherein the data file includes image data, and the number of threads corresponding to the plurality of threads equals a number of bytes in the data file.

18. The system of any of aspects 14-17, wherein the global offset is a first global offset, and the instructions, when executed, further cause the one or more processors to update the first global offset based on the optimal data sequence by: establishing a second global offset at a first data location within the data file that is a distance from the first global offset represented by a length value of the optimal data sequence.

19. The system of any of aspects 14-18, wherein the instructions, when executed, further cause the one or more processors to: calculate an offset value and a length value for each data sequence in the reference table; and compress the reference table using an entropy encoding algorithm.

20. A non-transitory computer-readable storage medium having stored thereon a set of instructions, executable by at least one processor, for massively parallel data compression, the instructions comprising: (a) instructions for receiving a data file; (b) instructions for establishing a global offset at a first data of the data file; (c) instructions for substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence; (d) instructions for determining an optimal data sequence corresponding to the first data sequence from the respective data sequences; (e) instructions for storing the optimal data sequence in a reference table; (f) instructions for updating the global offset based on the optimal data sequence; and (g) instructions for iteratively performing steps (c)-(f) until the global offset is a beginning or an end of the data file.

### ADDITIONAL CONSIDERATIONS

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Additionally, certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connects the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of the example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but also deployed across a number of machines. In some example embodiments, the processor or processors may be located in a single location (e.g., within a home environment, an office environment or as a server farm), while in other embodiments the processors may be distributed across a number of locations.

The performance of certain of the operations may be distributed among the one or more processors, not only residing within a single machine, but also deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the description. This description, and the claims that follow, should be read to include one or at least one and the singular also includes the plural unless it is obvious that it is meant otherwise.

While the present invention has been described with reference to specific examples, which are intended to be illustrative only and not to be limiting of the invention, it will be apparent to those of ordinary skill in the art that changes, additions and/or deletions may be made to the disclosed embodiments without departing from the spirit and scope of the invention.

The foregoing description is given for clearness of understanding; and no unnecessary limitations should be understood therefrom, as modifications within the scope of the invention may be apparent to those having ordinary skill in the art.

What is claimed:

1. A computer-implemented method for massively parallel data compression, the method comprising:
(a) receiving, at one or more processors, a data file;
(b) establishing, by the one or more processors, a global offset at a first data of the data file;
(c) substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence;
(d) determining, by the one or more processors, an optimal data sequence that minimizes non-matched data and maximizes matched data, the optimal data sequence corresponding to the first data sequence from the respective data sequences;
(e) storing, by the one or more processors, the optimal data sequence in a reference table;
(f) updating, by the one or more processors, the global offset based on the optimal data sequence; and
(g) iteratively performing steps (c)-(f) until the global offset is a beginning or an end of the data file.

2. The computer-implemented method of claim 1, wherein storing the optimal data sequence in the reference table further comprises:
storing, by the one or more processors, (i) a reference location and (ii) a length value of the optimal data sequence in the reference table.

3. The computer-implemented method of claim 1, wherein the optimal data sequence includes (i) a reference sequence or (ii) a literal sequence.

4. The computer-implemented method of claim 3, further comprising:
responsive to determining that the optimal data sequence is a literal sequence, storing the length of the literal sequence and a reference location of the literal sequence in a literal table.

5. The computer-implemented method of claim 1, wherein the data file includes image data.

6. The computer-implemented method of claim 1, wherein the number of threads corresponding to the plurality of threads equals a number of bytes in the data file.

7. The computer-implemented method of claim 1, further comprising:
receiving, by the one or more processors and after step (g), a search query to identify a feature represented in the data file; and
searching, by the one or more processors, the data file based on the reference table.

8. The computer-implemented method of claim 1, wherein the global offset is a first global offset, and updating the first global offset based on the optimal data sequence further comprises:
establishing a second global offset at a first data location within the data file that is a distance from the first global offset represented by a length value of the optimal data sequence.

9. The computer-implemented method of claim 1, further comprising:
calculating, by the one or more processors, an offset value and a length value for each data sequence in the reference table; and
compressing, by the one or more processors, the reference table using an entropy encoding algorithm.

10. The computer-implemented method of claim 1, further comprising:
storing, by the one or more processors at step (g), a reference representing a location of the first data sequence relative to (i) the beginning of the data file or (ii) the global offset.

11. The computer-implemented method of claim 1, further comprising:
comparing, by the one or more processors, a length value of the optimal data sequence with a match length threshold value;
responsive to determining that the length value does not exceed the match length threshold value, determining, by the one or more processors, a second optimal data sequence; and
responsive to determining that a second length value of the second optimal data sequence exceeds the match length threshold value, storing, by the one or more processors, the second optimal data sequence in the reference table.

12. The computer-implemented method of claim 1, further comprising:
at each iteration of steps (c)-(f), calculating, by the one or more processors, a compression index score for each thread of the plurality of threads by subtracting a respective number of non-matching characters from a respective number of matching characters; and
determining, by the one or more processors, a maximum compression index score from the compression index score for each thread of the plurality of threads.

13. The computer-implemented method of claim 1, further comprising:
calculating, by the one or more processors, a combined compression index score for each respective pair of threads from the plurality of threads by subtracting a number of overlapping matching characters and a number of residual non-matching characters from a combined number of matching characters; and
determining, by the one or more processors, a maximum combined compression index score from the combined compression index score for the each respective pair of threads of the plurality of threads.

14. A system for massively parallel data compression, comprising:
a memory storing a set of computer-readable instructions; and
one or more processors interfacing with the user interface and the memory, and configured to execute the set of computer-readable instructions to cause the one or more processors to:
(a) receive a data file,
(b) establish a global offset at a first data of the data file,
(c) substantially simultaneously cause a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence,
(d) determine an optimal data sequence corresponding to the first data sequence from the respective data sequences,
(e) store the optimal data sequence in a reference table,
(f) update the global offset based on the optimal data sequence, and
(g) iteratively perform steps (c)-(f) until the global offset is a beginning or an end of the data file.

15. The system of claim 14, wherein the instructions, when executed, further cause the one or more processors to store the optimal data sequence in the reference table by:
storing (i) a reference location and (ii) a length value of the optimal data sequence in the reference table.

16. The system of claim 14, wherein the optimal data sequence includes (i) a reference sequence or (ii) a literal sequence, and wherein the instructions, when executed, further cause the one or more processors to:
responsive to determining that the optimal data sequence is a literal sequence, store the length of the literal sequence and a reference location of the literal sequence in a literal table.

17. The system of claim 14, wherein the data file includes image data, and the number of threads corresponding to the plurality of threads equals a number of bytes in the data file.

18. The system of claim 14, wherein the global offset is a first global offset, and the instructions, when executed, further cause the one or more processors to update the first global offset based on the optimal data sequence by:
establishing a second global offset at a first data location within the data file that is a distance from the first global offset represented by a length value of the optimal data sequence.

19. The system of claim 14, wherein the instructions, when executed, further cause the one or more processors to:
calculate an offset value and a length value for each data sequence in the reference table; and
compress the reference table using an entropy encoding algorithm.

20. A non-transitory computer-readable storage medium having stored thereon a set of instructions, executable by at least one processor, for massively parallel data compression, the instructions comprising:
(a) instructions for receiving a data file;
(b) instructions for establishing a global offset at a first data of the data file;
(c) instructions for substantially simultaneously causing a plurality of threads of a graphics processing unit (GPU) to compare respective data sequences with a first data sequence that includes the first data, wherein each thread of the plurality of threads compares a respective data sequence of the respective data sequences, and each respective data sequence is offset from every other respective data sequence and the first data sequence;
(d) instructions for determining an optimal data sequence corresponding to the first data sequence from the respective data sequences;
(e) instructions for storing the optimal data sequence in a reference table;
(f) instructions for updating the global offset based on the optimal data sequence; and
(g) instructions for iteratively performing steps (c)-(f) until the global offset is a beginning or an end of the data file.
